(19) United States
(12) Patent Application Publication
(10) Pub. No.: US 2002/0100695 A1
(43) Pub. Date: Aug. 1, 2002

(54) Method and apparatus for an anodic treatment

(75) Inventors: Masato Sasaki, Kanagawa-ken (JP); Yuzuru Morioka, Kanagawa-ken (JP); Sachiko Sugita, Kanagawa-ken (JP); Masazumi Ishikawa, Kanagawa-ken (JP)

Correspondence Address: Richard L. Schwaab, Foley & Lardner, Washington Harbour, 3000 K Street, N.W., Suite 500, Washington, DC, 20007-5143, US

(73) Assignee: UNISIA JECS CORPORATION

(21) Appl. No.: 10/045,014

(22) Filed: Jan. 15, 2002

(30) Foreign Application Priority Data
Jan. 15, 2001 (JP) 2001-006525
Aug. 6, 2001 (JP) 2001-238157

(51) Int. Cl. C25D 5/02; C25B 9/00; C25C 7/00; H01L 21/288; B05C 3/02; C25D 17/00

(52) U.S. Cl. 205/333; 205/131; 205/133; 118/408; 204/275.1

(57) ABSTRACT

A method and apparatus for anodizing a component. The component is placed in a container having first and second seal members that seal an annular surface of the component to be anodized. The first and second seal members, the annular surface of the component, and an inner surface of the container form a reaction chamber that holds a reaction medium therein. The reaction medium is supplied to the reaction chamber through a supply passage formed in the container. The reaction medium is drained from the reaction chamber through a drain passage formed in the container.

### BACKGROUND OF THE INVENTION

1. Field of the Invention

This invention relates to a method and an apparatus for an anodic treatment on a surface of a piston used for an internal combustion engine. More particularly, the present invention relates to a method and an apparatus for anodizing an annular surface of the piston.

2. Description of the Related Art

It is well known that a portion of the piston used in the internal combustion engine is placed close to a combustion zone. More particularly the portion of the piston is in contact with relatively hot gases, and therefore, is subject to high-thermal stresses that may cause deformations or changes in the metallurgical structure. This negatively affects functions of the portion.

As a measure against such negative affections, a surface of the piston has been treated by an anodic treatment in order to develop an anodic oxide coating that protects a metal of the piston from undesirable affections of heat. One such apparatus that performs the anodic treatment is disclosed in, for example, a Japan Patent Publication (koukai) No. 9-217200 (incorporated herein by reference). According to the publication, as shown in FIG. 19, the apparatus includes a jacket 101, a lid member 102, a mask socket 103, an O-ring 105, an electrolyte bath 106, a nozzle system 107, a cathode 108, and an anode 109. The jacket bath 101 forms a part of a circulation circuit of electrolyte (reaction medium), and is substantially like a cup shape. The jacket 101 has an opening, which is closed by the lid member 102, at its upper end. A hole in which the mask socket 103 is fitted is formed at the center of the lid member 102. The mask socket 103 is substantially cylindrical in shape, and is provided its lower opening portion with an inwardly projected flange portion. A piston 104 is inversely placed in the mask socket 103. Namely, the piston 104 is inserted into the mask socket 103 from its head portion (piston head).

The O-ring 105 is placed on the flange portion. The O-ring 105 touches a surface of the piston head when the piston 104 is placed in the mask socket 103. Thereby, a portion of the piston not to be anodized is sealed. The nozzle system 107, through which the electrolyte is directed to the piston 104, is placed in the electrolyte bath 106 that is provided in the jacket 101. The cathode 108 is provided at an upper portion of the electrolyte bath 106. The anode 109 is in contact with the piston 104. The apparatus disclosed in the publication thus performs the anodic treatment on an end face of component (piston) that is cylindrical or columnar in shape.

According to the publication, however, since the O-ring 105 touches the surface of the piston head, there is a difficulty in anodizing a limited area defined at a middle portion on a cylindrical surface. That is, for instance, where the anodic treatment on the end face of the component (piston) is unnecessary while the anodic treatment on the limited area at the middle portion on the cylindrical surface is carried out, a masking of a portion of the component (the end face) is required to prevent the end face from being anodized. However, to make a mask portion, a masking process to the end face of the component must be accomplished before putting the component in the apparatus. This causes a decline of working efficiency and processing ability.

The electrolyte upwardly flows to the end face of the component through the nozzle system 107, and then, downwardly moves away from the end face to be drained from the electrolyte bath 106. The electrolyte supplied to the end face meets the electrolyte leaving from the surface, which causes an obstruction to a smooth circulation of the electrolyte. To provide the smooth circulation, a large area for flow of the electrolyte is necessary, and thereby, the size of the apparatus becomes large.

### SUMMARY OF THE INVENTION

According to an embodiment of the present invention a method for anodizing a component is provided. The method includes placing the component in a container having first and second seal members and sealing an annular surface of the component to be anodized using the first and second seal members to thereby form a reaction chamber bounded by the annular surface, the seal members and an inner surface of the container. The method further includes supplying a reaction medium to the reaction chamber through a supply passage formed in the container to thereby anodize the annular cylindrical surface.

In another embodiment, the method may further include the step of removing the reaction medium from the reaction chamber through a drain passage formed in the container. The steps of removing and supplying may be conducted simultaneously to thereby circulate the reaction medium through the reaction chamber.

According to an alternative embodiment of the present invention, an apparatus for anodizing a component is provided. The apparatus includes a container having a receiving hole for receiving the component into the container. The apparatus further includes first and second seal members for sealing an annular surface of the component to thereby form a reaction chamber between the container and the annular surface of the component.

The apparatus may further include a supply passage in the container for introducing a reaction medium into the reaction chamber and a drain passage for draining the reaction medium from the reaction chamber. The apparatus may also include a first electrode for energizing the component and a second electrode for energizing the container adjacent to the reaction chamber. Preferably, the container includes a passage plate having an opening for the component to extend through, wherein the passage plate includes a supply groove and a drain groove opening into the reaction chamber.

It is to be understood that both the foregoing general description and the following detailed description are exemplary and explanatory only, and are not restrictive of the invention as claimed.

### BRIEF DESCRIPTION OF THE DRAWINGS

These and other features, aspects and advantages of the present invention will become apparent from the following description, appended claims, and the accompanying exemplary embodiments shown in the drawings, which are briefly described below.

FIG. 1 is a sectional view of an anodizing apparatus according to a first embodiment of the present invention.

FIG. 2 is a front view of a passage plate according to the first embodiment of the present invention.

FIG. 3(a) is an enlarged sectional view of the passage plate taken on line A-A of FIG. 2.

FIG. 3(b) is an enlarged sectional view of an alternative embodiment of the passage plate taken on line A-A of FIG. 2.

FIG. 4 is a sectional view of an anodizing apparatus according to a second embodiment of the present invention.

FIG. 5 is a front view of a passage plate according to the second embodiment of the present invention.

FIG. 6 is a bottom view of the passage plate according to the second embodiment of the present invention.

FIG. 7 is a sectional view of the passage plate taken on line B-B of FIG. 5.

FIG. 8 is a sectional view of an anodizing apparatus according to a third embodiment of the present invention.

FIG. 9 is a sectional view of an anodizing apparatus according to a fourth embodiment of the present invention.

FIG. 10 is a sectional view of an anodizing apparatus according to a fifth embodiment of the present invention.

FIG. 11 is a sectional view of an anodizing apparatus according to a sixth embodiment of the present invention.

FIG. 12 is a sectional view of an anodizing apparatus according to a seventh embodiment of the present invention.

FIG. 13 is a sectional view of an anodizing apparatus according to an eighth embodiment of the present invention.

FIG. 14 is a sectional view taken on line C-C of FIG. 13.

FIG. 15 is a sectional view taken on line D-D of FIG. 13.

FIG. 16 is a sectional view of an anodizing apparatus according to a ninth embodiment of the present invention.

FIG. 17 is a sectional view of an anodizing apparatus according to a tenth embodiment of the present invention.

FIG. 18 is a sectional view taken on line E-E of FIG. 10.

FIG. 19 is a sectional view of an anodizing apparatus according to a conventional art.

### DETAILED DESCRIPTION

Accordingly, in view of above-described problems encountered in the conventional art, one object of the present invention is to provide a method and an apparatus for anodizing a component at a limited portion on its cylindrical surface made at a middle portion without requiring a masking procedure.

According to an embodiment of the present invention a method for an anodic treatment that comprises the operations of putting a component in a container is provided. The container is provided therein with a first and a second seal members. The method includes sealing a boundary between a portion being treated and another portion on a surface of the component by the first and second seal members for defining an annular cylindrical surface at a middle portion on the surface of the component. The first and second seal members, the annular cylindrical surface and an inner surface of the container form a reaction chamber that holds a reaction medium therein. The method further includes supplying the reaction medium to the reaction chamber through a supply passage formed in the container, and draining the reaction chamber from the reaction medium through a drain passage formed in the container.

According to another embodiment of the present invention, an apparatus for an anodic treatment includes a container that includes a receiving hole and a bottom portion. The container receives a component in the receiving hole thereof, and defines up and down directions and a horizontal direction. A first and a second seal members that is disposed in the receiving hole for sealing a boundary between a portion being treated and another portion on a surface of the component. The first and second seal members define an annular cylindrical surface at a middle portion on the surface of the component. A reaction chamber that is formed among the annular cylindrical surface, an inner surface of the container, and the first and second seal members. The reaction chamber holds a reaction medium therein. An inlet passage is formed in the container for introducing the reaction medium into the reaction chamber, an outlet passage formed in the container for draining the reaction chamber from the reaction chamber. The apparatus further includes a first electrode for conducting an electricity to the component, and a second electrode for conducting the electricity to the reaction medium.

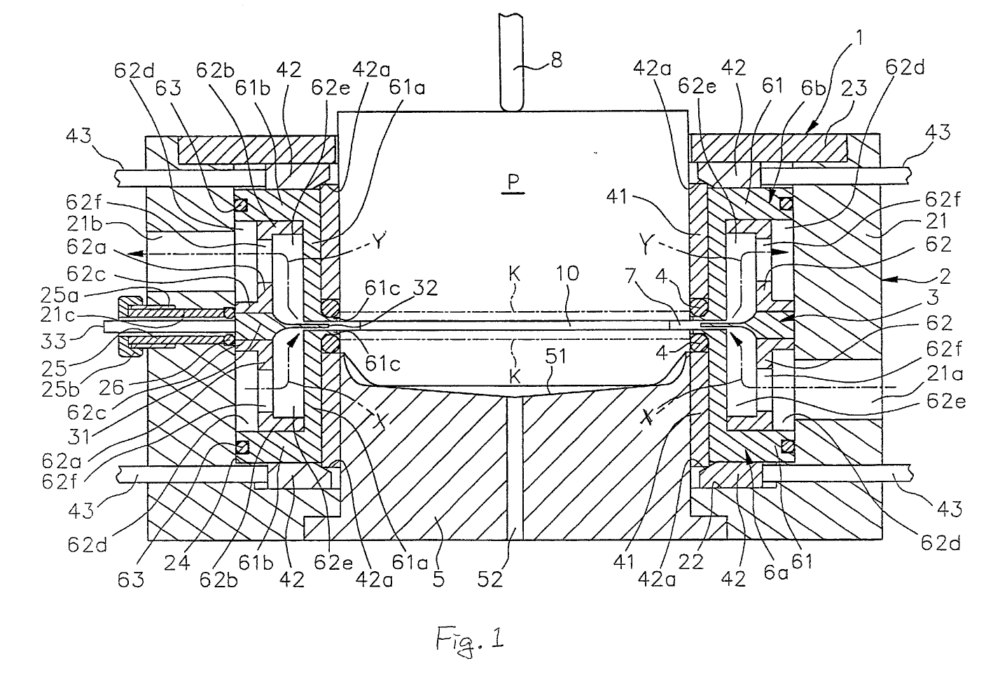

An apparatus for an anodic treatment according to preferred embodiments will now be described with a reference to the drawings. FIGS. 1-3 show a first embodiment of the present invention. According to the first embodiment of the present invention, the apparatus provides an anodic oxide coating on a surface of a top-ring groove of a piston P. As shown in FIG. 1, the apparatus comprises a container 1, an outer cylindrical member 2, a passage plate 3, a first and a second seal members (O-ring) 4, 4, and a push mechanism. The push mechanism comprises a first and a second sleeves 41, 41, a first and a second push rings 42, 42, and plural push rods 43. The container 1 may be cylindrical in shape, and includes a receiving hole (not numbered) for receiving the piston P with an inverted (upside-down) state, a bottom member 5, and a lower and an upper wall members 6a, 6b. The outer cylindrical member 2 includes a cylindrical wall section 21 and an inwardly projected flange section 22. An upper end of the cylindrical wall section 21 is closed by an annular cover member 23. The annular cover member 23 and the flange section 22 project inward, respectively, from the upper and a lower end of the outer cylindrical member 2, thus defining an annular groove that receives the lower and upper wall members 6a, 6b. The bottom member 5 forms a bottom portion of the container 1, and is substantially cylindrical in shape having an outer diameter approximately equal to an outer diameter of the piston P. The bottom member 5 is arranged in the outer cylindrical member 2, with its lower periphery being fitted in the flange section 22, to form the container 1.

While the shape of various components mentioned herein is described as cylindrical, this shape is merely preferred. The present invention includes within its scope a container, component and other mentioned elements having various shapes suitable for use with the apparatus and method described herein.

The lower and upper wall members 6a, 6b each comprise an exterior member and an interior member. That is, the lower wall member 6a includes an exterior member 61 and an interior member 62, and similarly, the upper wall member 6b comprises an exterior member 61 and an interior member 62. Each of the exterior members 61, 61 included in the lower and upper wall members 6a, 6b has a cylindrical section 61a, an outward flange section 6lb, and an inward flange section 61c. More particularly, in an assembled state as shown in FIG. 1, the outward flange section 61b is formed at a lower portion of the cylindrical section 61a of the lower wall member 6a, while the inward flange section 61c is provided at an upper portion. The inward flange section 61c of the exterior member 61 included in the lower wall member 6a positions and supports the first O-ring 4. The exterior member 61 is arranged in the annular groove of the outer cylindrical member 2 having an end face of the outward flange section 61b in an abutted contact with a stepped portion 24 formed on the flange section 22.

The first sleeve 41 is disposed between the exterior member 61 of the lower wall member 6a and the bottom member 5, with a slidable contact in an axial direction of the outer cylindrical member 2, to push the first O-ring 4. The first push ring 42 is arranged between the flange section 22 and the outward flange section 61b of the exterior member 61 included in the lower wall member 6a with a slidable contact in a radial direction of the outer cylindrical member 2. The first push ring 42 is provided thereon with a tapered surface 42 that is in contact with a lower end portion of the first sleeve 41. Also, the first push ring 42 is arranged in a space defined between an upper surface of the flange section 22 and the end face of the outward flange section 61b of the lower wall member 6a. The push rods 43 are slidably received in holes radially formed in the cylindrical wall section 21, and are arranged to push the push ring 42 in an inward direction thereof.

The interior member 62 included in the lower wall member 6a comprises, in the assembled state, a cylindrical section 62a, an inward flange section 62b formed at a lower portion of the cylindrical section 62a, and an outward flange section 62c formed at an upper portion of the cylindrical section 62a. There are formed plural holes 62f in the cylindrical section 62a. Thereby, an inner space 62e and an outer space 62d communicate with each other. The inner space 62e is defined between the exterior member 61 and the interior member 62, and the outer space 62d is provided between the interior member 62 and the outer cylindrical member 2.

Similarly to the lower wall member 6a, the upper wall member 6b also includes the exterior member 61 and the interior member 62, both of which are shaped approximately like inverted forms of the exterior and interior members 61, 62 of the lower wall member 6a, respectively. Namely, the exterior and interior members 61, 62 of the upper wall member include cylindrical sections 61a, 62a, outward flange sections 61b, 62c, and inward flange sections 61c, 62b, respectively, and are arranged above the lower wall member 6a so that the passage plate 3 is pinched between the outward flange sections 62c, 62c of the interior members 62, 62, thereby forming a reaction chamber 7 between the inward flange sections 61c, 61c of the exterior members 61, 61. Axial dimensions of the passage plate 3, the exterior members 61, 61, and the interior members 62, 62 are determined so as to form the reaction chamber 7.

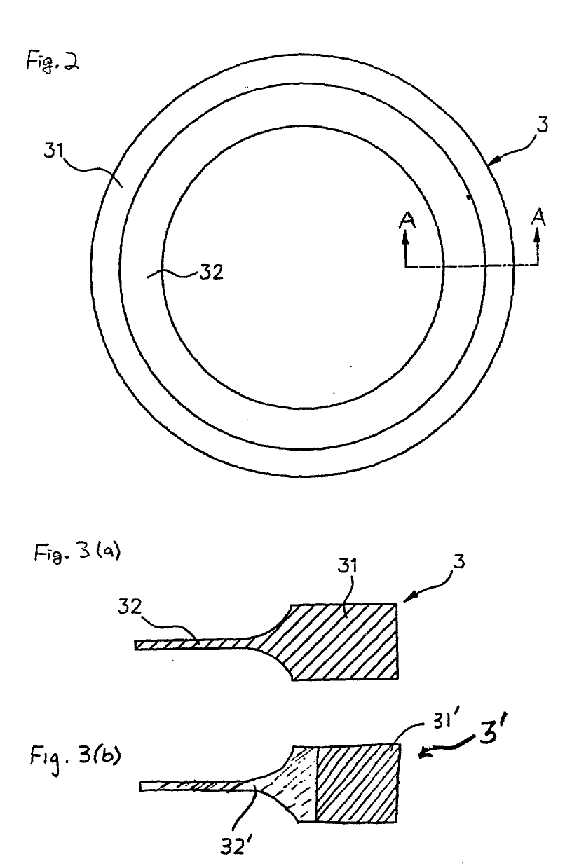

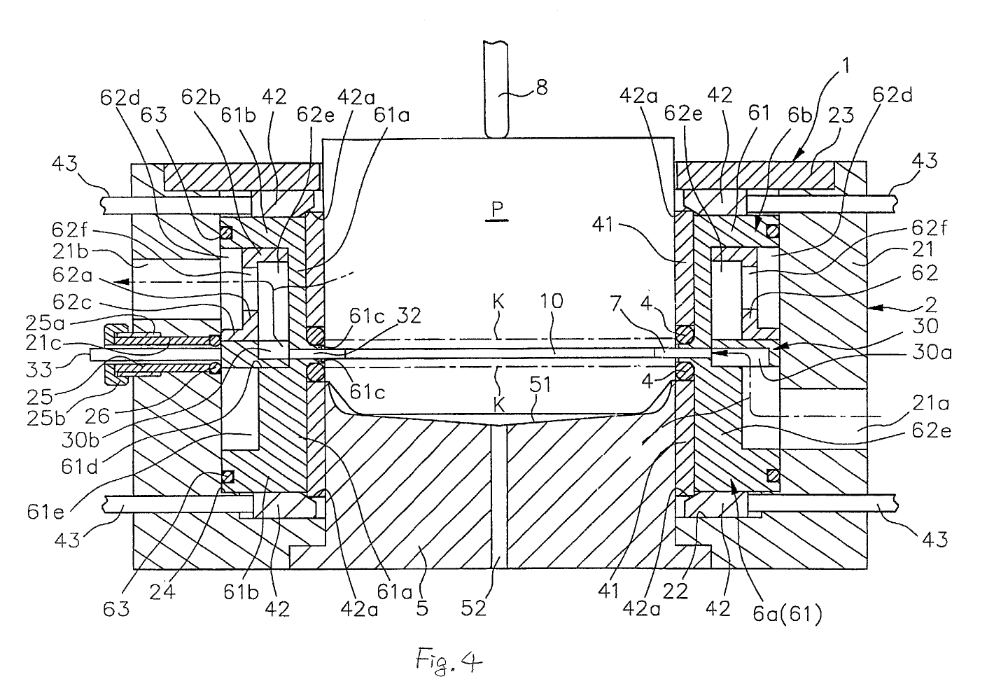

There are provided a first and a second sealing rings 63, 63 to seal contact surfaces between the outer cylindrical member 2 and the exterior members 61, 61 included in the lower and upper wall members 6a, 6b, respectively. The passage plate 3 has a main section 31 and an inner section 32 projecting inwardly from the main section 31 (shown in FIGS. 2 and 3(a)). The inner section 32 is formed integrally with the main section 31 having a thinner thickness than a thickness of the reaction chamber 7 in up and down directions thereof. As shown in FIG. 1, the passage plate 3 is arranged so that a tip of the inner section 32 is placed at a middle portion of the reaction chamber 7 in a radial direction of the reaction chamber 7.

The second sleeve 41 is arranged on an inner side of the exterior member 61 included in the upper wall member 6b with a slidable contact in its axial direction, i.e., up and down directions of the component. The second sleeve pushes the second O-ring 4 downwardly. Also, the second push ring 42 is provided between the annular cover member 23 and the outward flange section 61b of the exterior member 61 included in the upper wall member 6b with a slidable contact in the radial direction of the outer cylindrical member 2. The second push ring 42 has a tapered surface 42a that is in contact with an upper end of the second sleeve 41, and is disposed in order to be pushed toward a center thereof by the push rods 43. The cylindrical wall section 21 of the outer cylindrical member 2 has an inlet 21a and an outlet 21b. The inlet 21a communicates with the outer space 62d at a lower portion of the outer space 62d, while the outlet 21b is in communication with the outer space 62d at an upper portion of the outer space 62d, in an axial direction of the piston P. Namely, as shown in FIG. 1, an inlet passage X, which is in communication with the inlet 21a and the reaction chamber 7, is defined by lower portions of the outer and inner spaces 62d, 62e, and the holes 62f. On the other hand, an outlet passage Y, which is in communication with the reaction chamber 7 and the outlet hole 21b, is defined by upper portions of the outer and inner spaces 62d, 62e, and the holes 62f.

Dimensions of above described elements are preferably determined that a position of a top ring groove 10 of the piston P becomes identical to that of the reaction chamber 7 in the axial direction of the piston P, having the first and second O-rings 4, 4 located nearby upper and lower edges of the top ring groove 10, respectively, when the receiving hole of the container 1 receives the piston P in the inverted state with a bottom surface of the piston P (piston head) abutting a concave portion 51 formed on an upper surface of the bottom member 5. Thereby, upper and lower boundary lines K, K, which define an area to be anodized, are determined.

The outer cylindrical member 2 has a penetration hole 21c, which receives a push tube 25, at a portion that faces to an outer cylindrical surface of the passage plate 3. There is provided a sealing ring 26 in the penetration hole 21c. The push tube 25 exerts the sealing ring 26 to prevent a leakage of the reaction medium into the penetration hole 21c. A conductive rod 33 is inserted into the push tube 25 having an end portion thereof abutted the outer cylindrical surface of the passage plate 3 that acts as an electrode. Namely, the conductive rod 33 is arranged so as to abut the passage plate 3 at a portion not to be exposed in the reaction medium and an outside of passages of the reaction medium. The push tube 25 is fixed in the penetration hole 21c, with a pushed state toward the passage plate, by a screw tube 25a and a screw 25b. That is, the screw tube 25a is secured to the outer cylindrical member 2, and the screw 25b, in turn, is fixed to the screw tube 25a. A drain hole 52 is provided at a center of the concave portion 51 for draining the reaction medium that might leak from the reaction chamber 7 when the piston P is removed from the receiving hole. Also, another electrode 8 is provided so as to abut the piston P when the piston is received in the receiving hole.

As described previously, according to the first embodiment of the present invention, when the first and second push rings 42, 42 are urged inwardly by the push rods 43, 43 having the piston P received in the receiving hole, the annular tapered surfaces 42a, 42a of the first and second push rings 42, 42 abut the upper end of the first sleeve 41 and the lower end of the second sleeve 41, respectively. Thus, the first and second sleeves 41, 41 move in those axial directions, and compress the first and second O-rings 4, 4, respectively. By virtue of the compression by the axial movement of the sleeves 41, 41, the O-rings 4, 4 shorten their inner diameters in the axial direction of the piston P. Thereby, the O-rings 4, 4 abut the boundary lines K, K providing a sealing function. The reaction chamber 7 that holds the reaction medium is formed among an annular surface of the piston P (a portion being anodized), the first and second O-rings 4, 4 and an inner surface of the receiving hole. The annular cylindrical surface of the piston P includes a surface of the top ring groove 10.

When a pump (not shown) is started, the reaction medium is supplied to the reaction chamber 7 through the inlet 21a and the inlet passage X, i.e., the outer space 62d, the holes 62f and the inner space 62e. Then, the reaction medium is directed to the surface of the top ring groove 10 passing through a lower side of the inner section 32 of the passage plate 3. Through an upper side of the inner section 32 of the passage plate 3, the reaction medium leaves the reaction chamber 7, and then, flows to the outlet passage Y, i.e., the inner space 62e, the holes 62f, the outer space 62d and the outlet 21b. At this time, direct current is supplied to the passage plate 3 and the electrode 8 in order to carry out an anodizing reaction. Thereby, the anodic treatment on a limited portion of the piston P including the surface of the top ring 10 can be annularly provided.

As detailed above, after the piston P is placed in the receiving hole, the O-rings 4, 4 abut the cylindrical surface of the piston P providing the boundary lines K, K that determine the annular cylindrical surface, by axial movements of the first and second sleeves 41, 41 caused by inward movements of the push rods 43. Thus, the anodic treatment at the middle portion on the cylindrical surface of the piston P is provided without requiring a masking procedure. This brings a reduced working efficiency and a processing capability. Further, according to the first embodiment of the present invention, the area that is exposed to the reaction medium is made narrower by the O-rings 4, 4, so that less electric power is necessary, as compared to the conventional apparatus for anodizing the piston top surface. Thereby, a heat generation is reduced. Also, since volume of the reaction chamber 7 is small and a flow of the reaction medium is formed in the horizontal direction of the passage plate 3, a flow velocity of the reaction medium is obtained with a smooth flow. This provides an improvement in a cooling efficiency of the reaction medium. By this reason, a lower capability of a cooling machine for the reaction medium is required. Also, a volume of the reaction medium necessary for the anodic treatment of the piston is reduced.

A volume of the reaction chamber 7 is dimensioned in accordance with an area of the annular cylindrical surface, so that the reaction chamber circulates in the reaction chamber with high-efficiency. Thus, it becomes possible to downsize the apparatus. Also, because of the area of the annular cylindrical surface that is dimensioned narrowly, the amount of harmful gases, such as hydrocarbon, that might adhere to an anodized surface is reduced. The reaction medium is supplied uniformly and simultaneously to the annular cylindrical surface from its periphery, so that a uniform treatment of the anodization is performed in the circumferential direction of the piston P. Furthermore, the outlet 21b is provided at a higher position than that of the outlet passage Y, and thus an air mixed in the reaction medium is efficiently exhausted when the reaction medium leaves the container through the outlet 21b. Therefore, an uneven reaction of the anodic treatment may be caused by the air mixed in the reaction medium. The inner section 32 is placed in the reaction chamber 7 in order to divide the reaction chamber 7 in up and down directions thereof. Thereby, in a high efficiency, the reaction medium circulates in the reaction chamber 7 that is reasonably dimensioned in accordance with the area of the annular cylindrical surface, and thus, downsizing of the apparatus is obtained.

One of electrodes exposed to the reaction medium may comprise the passage plate 3 that is arranged in the reaction chamber 7, so that the electrode is located nearby the piston P within a narrow area. By virtue of this arrangement, a reaction efficiency is improved. Moreover, the conductive rod 33 provided for carrying an electricity to the passage plate 3 is disposed outside the reaction chamber 7 so as not to be exposed to the reaction medium, thereby preventing a corrosion of a point of the conductive rod 33 and the passage plate 3 that might be caused by the reaction medium.

As shown in FIG. 3(b) the passage plate 3′ may be formed so that the inner section 32′ is not energized by the electrode (i.e., remains de-energized). The main section 31′ is in contact with the conductive rod 33 and is energized during the anodic treatment of the component to function as the required electrode for anodization (i.e., the cathode).

It is possible for sparks to be generated between anodization electrodes located in close proximity (i.e. between the piston and the passage plate). The occurrence of sparks is detrimental to the formation of a high-quality anodization layer at the top ring groove of the piston. As described above, an embodiment of the present invention provides for the separation of the passage plate into conductive and non-conductive sections. This arrangement helps to prevent the formation of sparks. The piston (anode) and the conductive or main section of the passage plate (cathode) are separated by the inner or non-conducctive section of the passage plate. The main section 32′ is arranged to contact the reaction medium in the inlet passage and not in the reaction chamber. The non-conductive or inner section 32′ extends into the reaction chamber adjacent the piston thereby separating the electrodes and inhibiting the generation of sparks around the top ring groove of the piston.

The lower and upper wall members 6a, 6b, which are separable in up and down directions based on the treating area (the surface of the top ring groove 10), and the bottom member 5 include a portion that forms at least the receiving hole of the container 1. The first and second O-rings 4, 4 are provided on the lower and upper wall members 6a, 6b. The passage plate 3 that constitutes one of electrode exposed to the reaction medium is disposed between the lower and upper wall members 6a, 6b, being pinched therebetween. The lower and upper wall members 6a, 6b, the passage plate 3 and the annular cylindrical surface of the piston P cooperatively define the reaction chamber 7. Also, the inlet passage X that communicates with the reaction chamber 7 is formed on the lower wall member 6a, whereas the outlet passage Y is formed on the upper wall member 6b. Thus, the container 1 that has the inlet and outlet passages X, Y, both communicating with the reaction chamber 7, is assembled easily by stacking those elements in up and down directions.

Next, an anodizing apparatus according to a second embodiment will be described. In this embodiment, the same or similar references used to denote elements in the anodizing apparatus of the first embodiments will be applied to the corresponding elements used in the second embodiment, and only the significant differences from the first embodiment will be described. FIG. 4 shows a sectional view of the second embodiment of the present invention.

The anodizing apparatus of the second embodiment is similar to the first embodiment shown in FIGS. 1-3, except that it provides an alternative structure for the passage plate 30 and the lower wall member 6a. Namely, the lower wall member 6a comprises only the exterior member 61. Also, except at an upper end portion thereof, the cylindrical section 61a is provided with a heavier wall thickness than that of the first embodiment so that a stepped portion 61d is formed thereon. According to the second embodiment of the present invention, only the outer space 61e is defined in the lower wall member 6a, whereas the lower wall member 6a of the first embodiment defines the outer and inner spaces 62d, 62e.

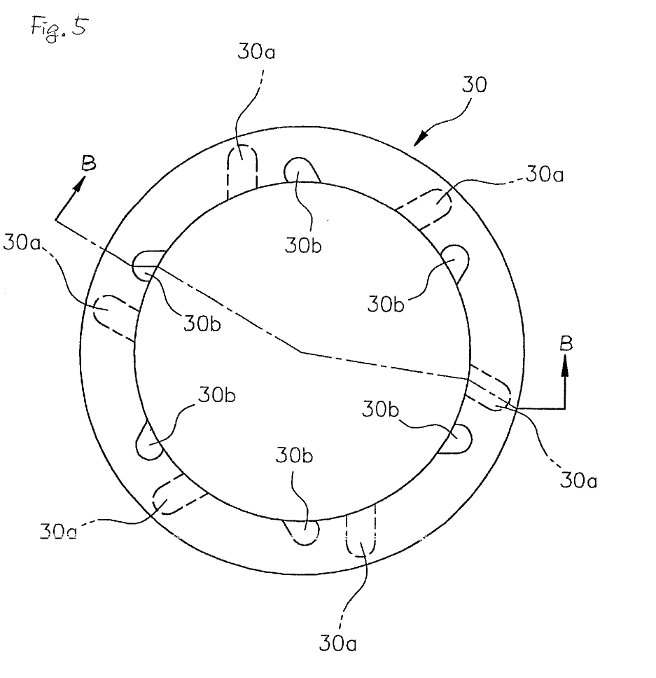

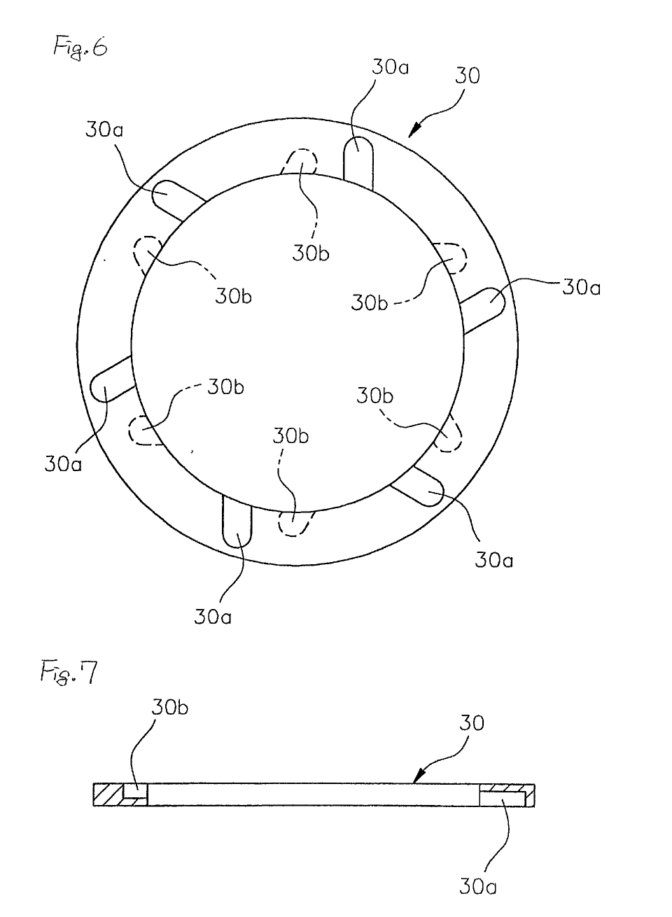

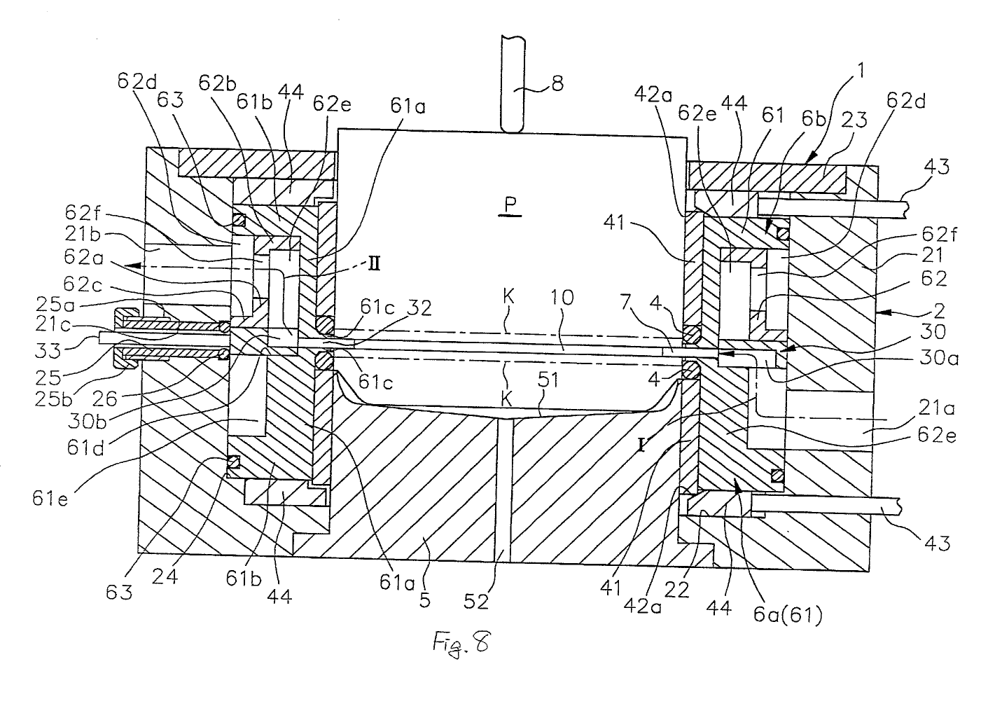

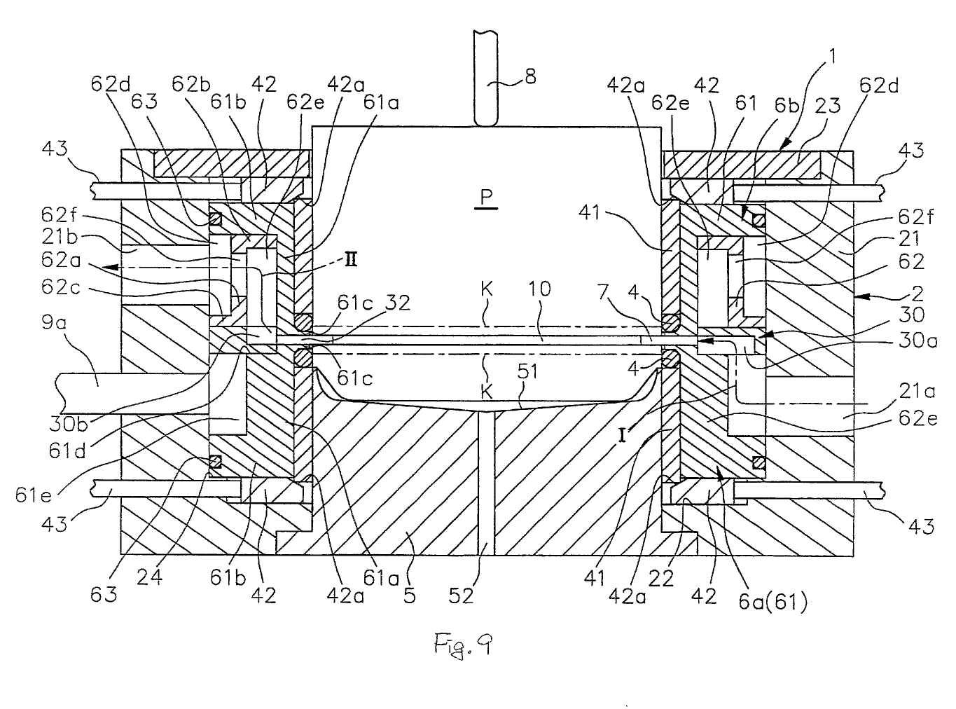

As shown in FIGS. 5-7, the passage plate 30 includes six supply grooves 30a and six drain grooves 30b. Each of the supply grooves 30a constitutes a part of the inlet passage X, and is preferably formed on a lower face of the passage plate 30. Similarly, each of the drain grooves 30b constitutes a part of the outlet passage Y, and is formed on an upper face of the passage plate 30. The supply grooves 30a are provided in the same interval. The drain grooves 30b are also arranged in the same interval. The supply grooves 30a and the drain grooves 30b are formed alternately together in the circumferential direction of the passage plate 30 so that each supply groove 30a does not overlap with any of drain grooves 30b in an axial direction of the passage plate 30.

As shown in FIGS. 5 and 6, the supply grooves 30a and the drain grooves 30b have angles by which the reaction medium is directed or leaves the annular cylindrical surface of the piston P having a predetermined angle. The angles of the supply and drain grooves 30a, 30b are determined so that the angle of a supply groove relative to the tangent to the piston P at the supply groove is opposite to the angle of a drain groove relative to the tangent to the piston P at the drain groove. The angles of the drain and supply grooves are symmetrical about a line perpendicular to the surface to be anodized. The direction of each supply groove 30a is angled toward an opposite direction to that of each drain passage 30b. The passage plate 30 is disposed between the outward flange section 62c of the interior member 62 and the stepped portion 61d of the exterior member 61, being pinched therebetween.

When the pump starts to operate, the reaction medium is introduced, through the supply grooves 30a and the supply passage X (namely, the outer space 61e), into the reaction chamber 7 in which the reaction medium is directed toward the piston P at the predetermined angle. Then, the reaction medium leaves the reaction chamber 7 having at the predetermined angle through the drain grooves 30b, and flows to the outlet 21b through the drain passage Y (namely, the outer space 62e of the upper wall member 6b, the holes 62f, and the outer space 62d).

Thus, according to the second embodiment of the present invention, an increased velocity and a smooth flow of the reaction chamber is obtained by virtue of following features, which requires a lesser performance of a cooling machine for cooling the reaction medium, as compared to the conventional art. First, the axial directions of the supply grooves 30a and drain grooves 30b are in a horizontal direction of the passage plate 30, and are substantially the same level as that of the top ring groove 10 in the axial direction of the piston P. Second, plural supply grooves 30a and drain grooves 30b (in this embodiment, six supply grooves and drain grooves) are arranged on both sides of the passage plate 30 having those arranged alternately with each other. Third, directions of the supply grooves 30a are at a pre-determined angle to the surface of the piston P, while directions of the drain grooves 30b are at an angle opposite to that of the supply grooves 30a.

Next, an anodizing apparatus according to a third embodiment of the present invention now will be described. FIG. 8 is a cross sectional view of the third embodiment. As will be appreciated, this embodiment is similar to the second embodiment, except that a rigid member 44 is used in place of one part of the first and second push rings 42, 42, and that the push rods 43, 43 are provided on only one side of the container 1. Therefore, the number of parts and a cost of the apparatus are both reduced.

FIG. 9 is a cross sectional view of a fourth embodiment of the present invention. As will be appreciated, the third embodiment is substantially the same as the second embodiment. The main difference from the second embodiment is that one of the electrodes that is exposed to the reaction medium comprises an electrode rod 9a whereas the electrode of the second embodiment comprises the passage plate 30. Namely, the electrode rod 9a passes through the outer cylindrical member 2 in the radial direction of the container 1, so that an end portion of the electrode rod 9a is exposed to the reaction medium.

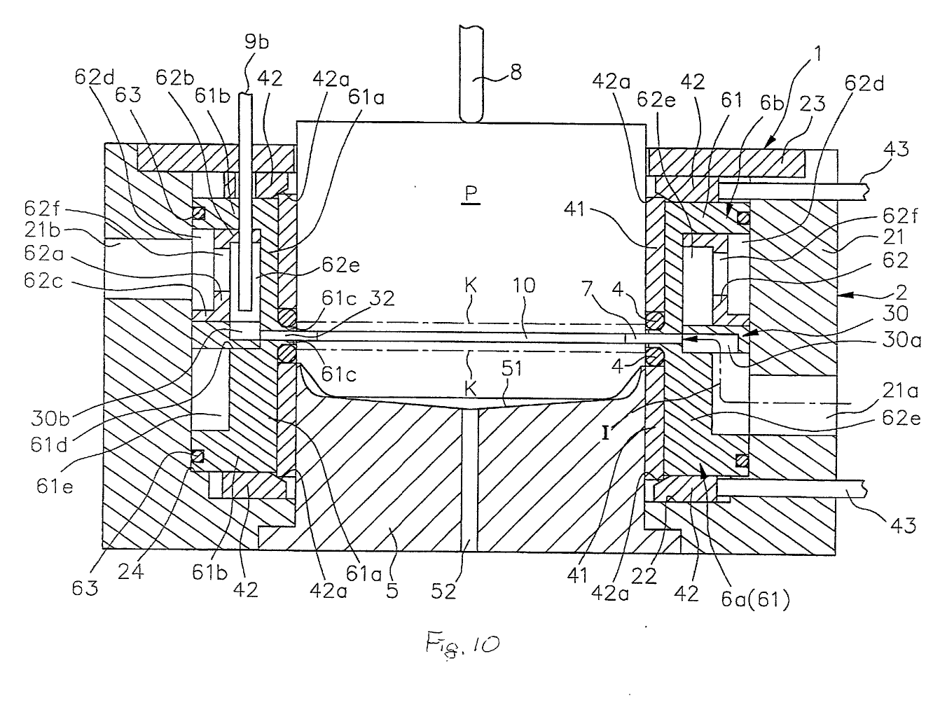

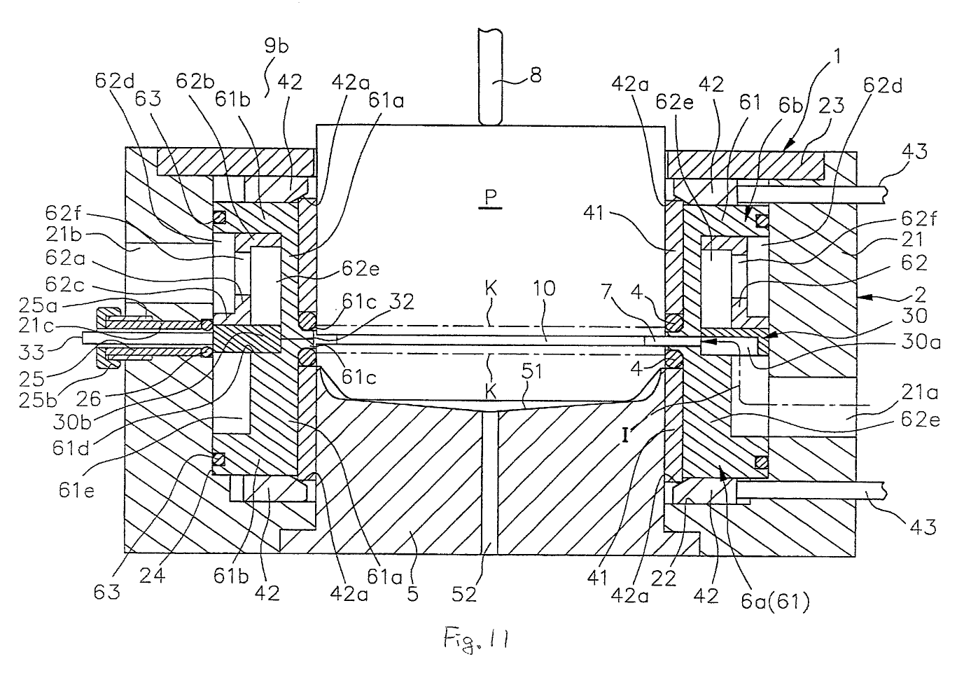

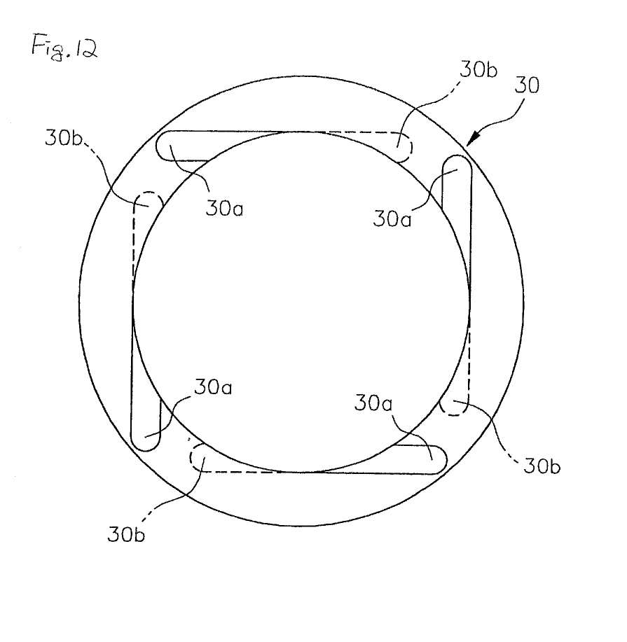

FIG. 10 is a cross sectional view of a fifth embodiment of the present invention. Similarly to the fourth embodiment, one of electrodes that is exposed to the reaction medium comprises an electrode rod 9b. The difference in this embodiment from the fourth embodiment is that the electrode rod 9b penetrates annular cover member 23, the rigid member 44, and the upper wall member 6b, having its bottom end exposed to the reaction medium. Both the fourth and fifth embodiments provide, in addition to the features described in the second embodiment of the present invention, a simplified structure of the apparatus.

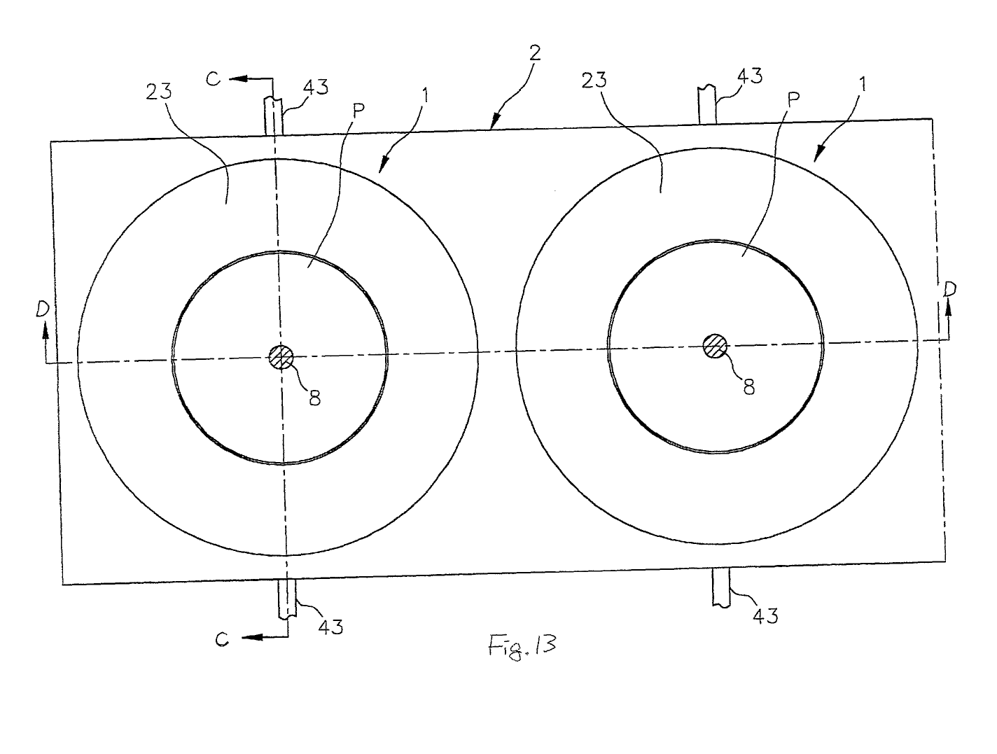

FIG. 11 is a cross sectional view of a sixth embodiment of the present invention. As shown in FIG. 11, this embodiment is substantially the same as the second embodiment, except that a part of the exterior member 61 included in the upper wall member 6b and the lower wall member 6a abut with each other at a place other than which the supply and drain grooves 30a, 30b are formed. Since the lower and upper wall members 6a, 6b abut with each other, the width of the reaction chamber 7 in the axial direction of the piston P is secured. Also, the annular cylindrical surface may be freely selected in the radial direction of the piston P by selecting a radial position of the abutting portion of the lower and upper wall members 6a, 6b.

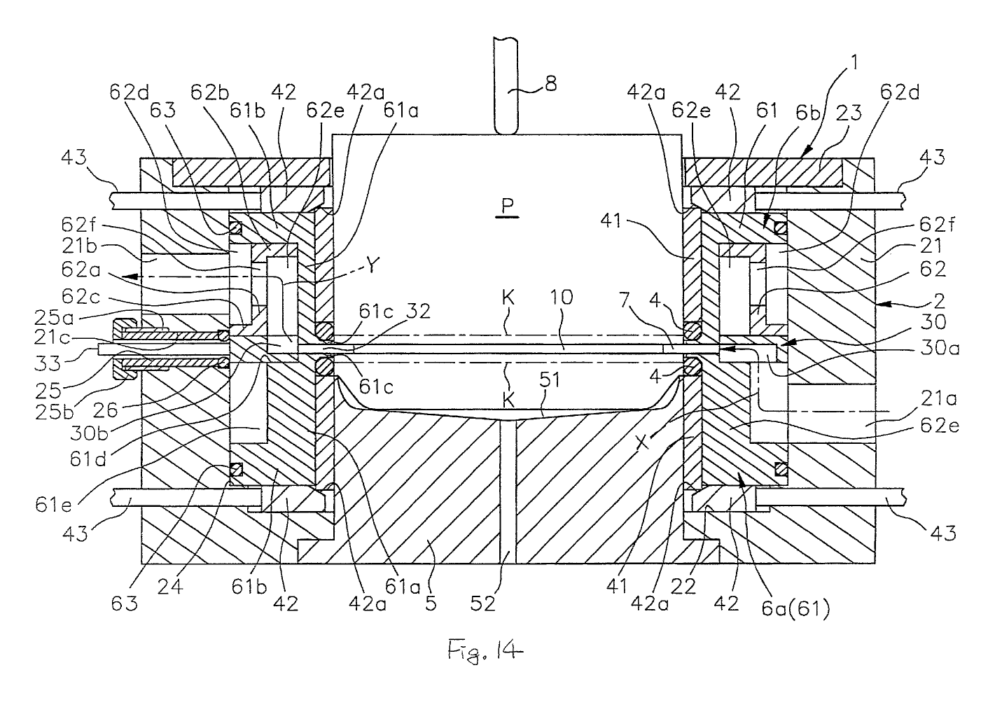

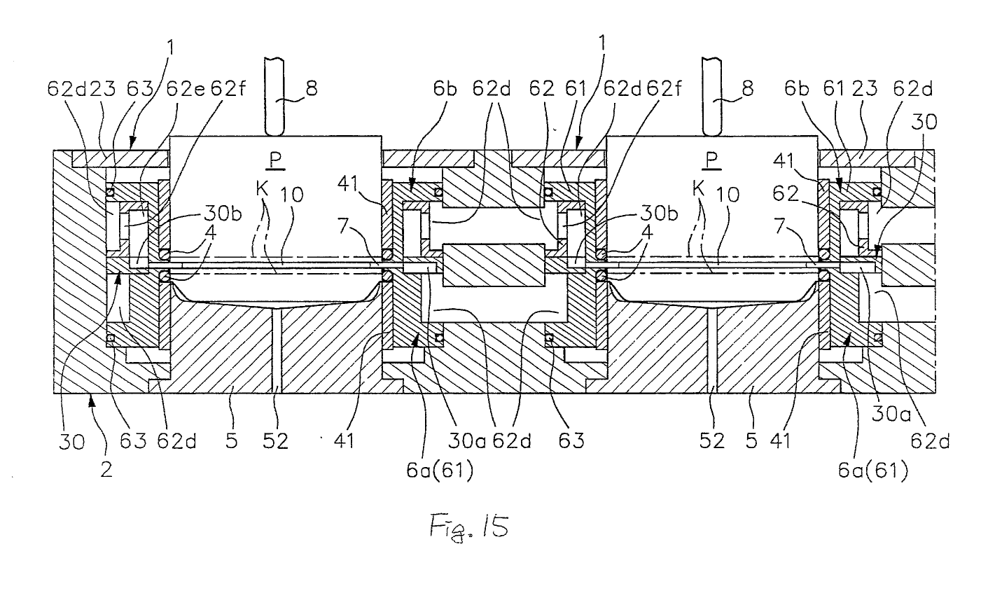

FIG. 12 shows a bottom view of the passage plate 30 of a seventh embodiment of the present invention. As shown in FIG. 12, the supply and drain grooves 30a, 30b are formed so that those axial lines are parallel with the tangents to the piston P. Thus, the reaction medium is introduced into the reaction chamber 7 having at angle of approximately 0 degrees. In this case, a capability of the anodic treatment is improved by virtue of the smooth flow of the reaction medium obtained by this embodiment. FIGS. 13-15 show a eighth embodiment of the present invention. As shown in FIG. 13, plural apparatuses that are substantially the same as the second embodiment are coupled together. That is, as shown in FIG. 15, the outer spaces 61d, 61aof adjoining apparatuses are connected with each other, while the upper outer spaces 62d, 62d are coupled together at a connecting portion between adjoining apparatuses. Thereby, plural apparatuses are coupled together in a compact shape.

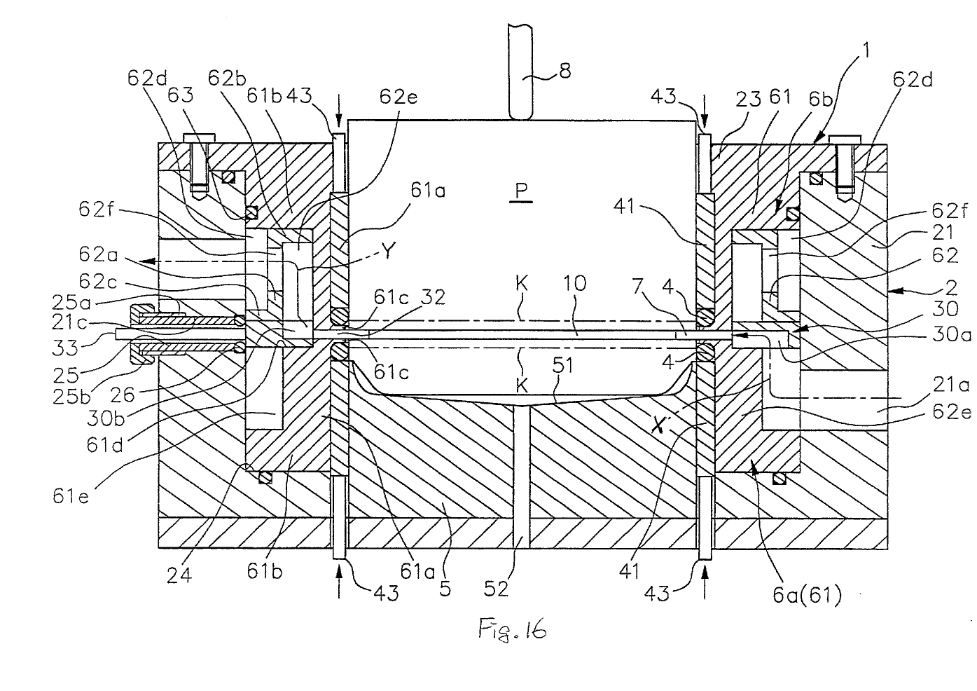

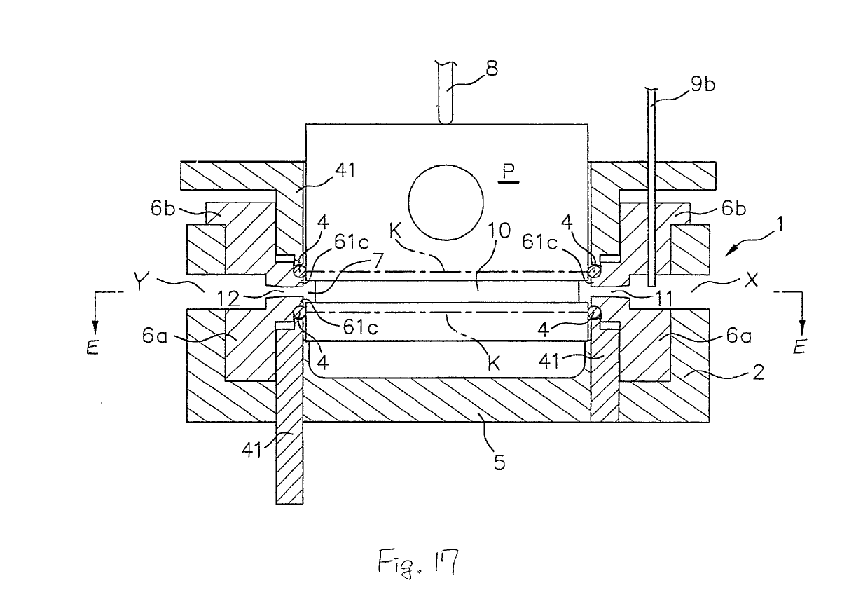

In FIG. 16, there is shown a ninth embodiment. As will be appreciated, the ninth embodiment is substantially the same as the second embodiment of the present invention, except that another way is employed for the push mechanism for compressing the first and second O-rings 4, 4. Namely, the apparatus in this embodiment does not include the first and second push rings 42, 42. Instead of this, the push rods 43, 43 directly press the first and second sleeves 41, 41 in the axial directions of the first and second sleeves 41, 41, respectively. Furthermore, the exterior member 61 included in the upper wall member 6b is formed integrally with the annular cover member 23. Therefore, in addition to the feature obtained by the second embodiment of the present invention, simplicity in the structure of the apparatus is obtained. Moreover, where the passage plate 30, the interior member 62, the exterior member 61, and the annular cover member 23 are assembled together as an unified unit, an easy attachment and detachment of the unit is obtained with a reduced time in changing the unit. The first and second sleeves 41, 41 may be assembled together with the unified unit.

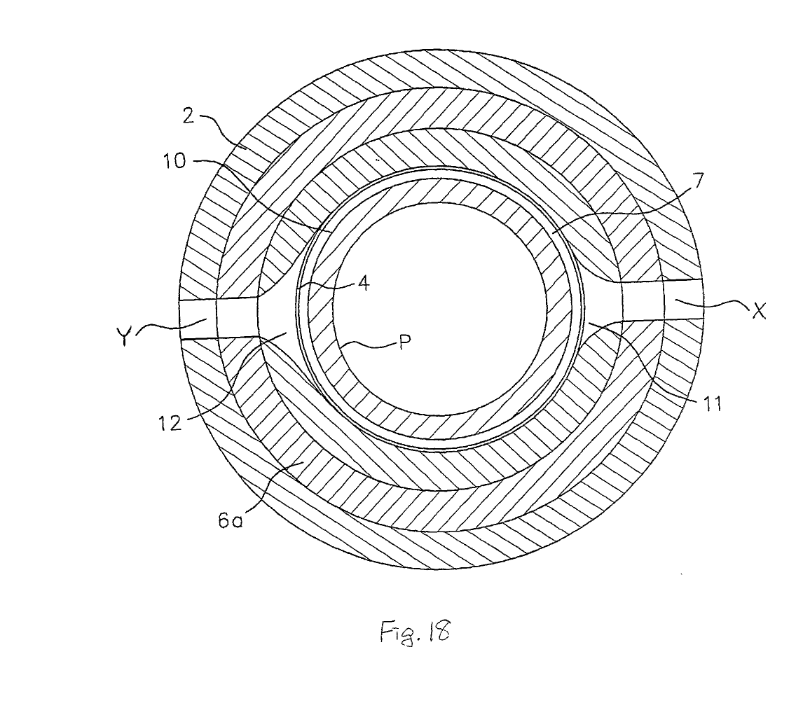

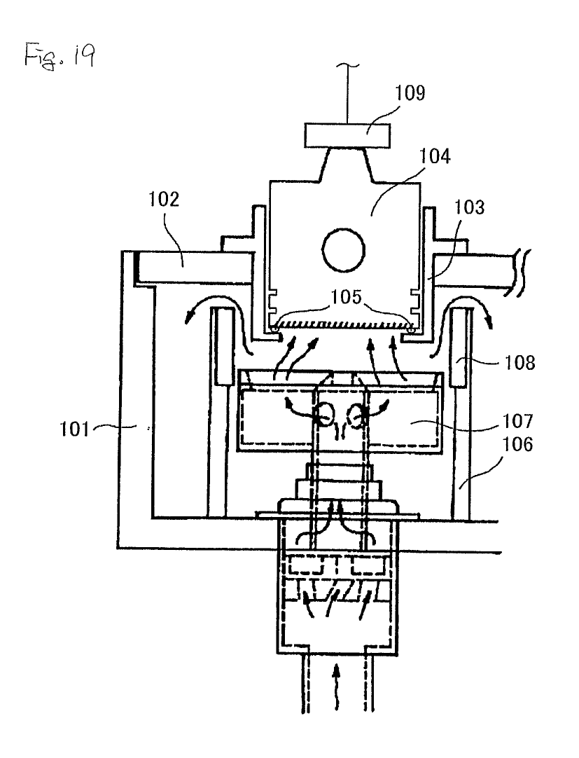

FIGS. 17 and 18 show a tenth embodiment of the present invention. As shown in both Figures, as a modified example of the fifth embodiment of the present invention the electrode rod 9b of which is arranged separately with the passage plate 30, this embodiment does not include the passage plate 30. Namely, according to the tenth embodiment of the present invention, the container 1 is provided with the supply passage X and the drain passage Y. The supply and drain passages X, Y are placed at opposing positions with respect to each other in the radial direction of the container 1. As shown in FIG. 17, the supply and drain passages X, Y have narrow portions 11, 12, both working as orifices, respectively. The height of both portions 11, 12 in the axial direction of the piston P is smaller than the height of the supply and drain passages X, Y, respectively. As shown in FIG. 18, the circumferential widths are dimensioned so that the width increases toward the reaction chamber 7. This arrangement prevents an increase in temperature of the reaction medium caused by concentrations of the reaction medium that occur at places where the supply and drain passages X, Y have opening portions to the reaction chamber 7.

The increase in the temperature of the reaction medium is more marked on a drain passage side than a supply passage side. Thus, the narrow portions 11, 12 are dimensioned that a width of the narrow portion 12 is wider than that of the narrow portion 11. Although not required, it is preferable that the ratio of the circumferential width at the opening portion of the narrow portion 11 to that of the narrow portion 12 is determined from the range of between 1:1.5 through 1:3. In brief, the ratio may be determined so that the reaction medium in the reaction chamber 7 introduced through the supply passage X smoothly leaves the reaction chamber 7 without being stuck.

As described above, the flow of the reaction medium in the supply passage X is narrowed in a vertical direction of the supply passage X while broadened in the circumferential direction. This provides the smooth flow of the reaction medium in the reaction chamber 7 by which uniformity in contact of the reaction medium with the annular cylindrical surface is efficiently obtained. Thus, according to the tenth embodiment of the present invention, simplicity in the structure of the apparatus is obtained by an omission of the passage plate 30 and a structure of the supply and drain passages X, Y.

While the present invention is described on the basis of certain preferred embodiments, it is not limited thereto, but is defined by the appended claims as interpreted in accordance with applicable law. For example, according to the previously described preferred embodiments of the present invention, although the piston is used as an object for anodization, all metal products that have a middle portion to be anodized on an outer surface in those axial directions may be anodized.

This application relates to and incorporates herein by reference Japanese Patent application No. 2001-238157 filed on Aug. 5, 2001, and No. 2001-6525 filed on Jan. 15, 2001 from which priority is claimed.

What is claimed is:

1. A method for anodizing a component comprising the steps of:
placing the component in a container having first and second seal members;
sealing an annular surface of the component to be anodized using the first and second seal members to thereby form a reaction chamber bounded by the annular surface, the seal members and an inner surface of the container;
supplying a reaction medium to the reaction chamber through a supply passage formed in the container to thereby anodize the annular cylindrical surface.

2. The method of claim 1, wherein the step of supplying the reaction medium includes continuously circulating reaction medium through the reaction chamber.

3. The method of claim 1, further comprising the step of removing the reaction medium from the reaction chamber through a drain passage formed in the container.

4. The method of claim 3, wherein the steps of removing and supplying are conducted simultaneously to thereby circulate the reaction medium through the reaction chamber.

5. The method of claim 3, further comprising providing a passage plate in the container, the plate having the supply and drain passages, and wherein the component extends through an opening in the passage plate.

6. The method of claim 5, wherein the supply passage and the drain passage are formed on opposite faces of the passage plate.

7. The method of claim 5, further comprising the step of energizing the passage plate and the component to thereby form anodization electrodes.

8. The method of claim 7, wherein during the step of energizing the passage plate a portion of the passage plate adjacent the reaction chamber remains deenergized.

9. The method of claim 5, wherein the supply and drain passages each comprise a plurality of supply and drain grooves, respectively.

10. The method of claim 9, wherein the supply and drain grooves are arranged alternately around the opening of the passage plate.

11. The method of claim 3, wherein the reaction fluid is supplied into the reaction chamber and removed from the reaction chamber at different angles relative to the surface of the component.

12. The method of claim 5, wherein, the supply and drain passages are formed on an inner section of the passage plate to direct and drain the reaction medium from the reaction chamber at an angle of 90 degrees with respect to a line tangent to the component.

13. An apparatus for anodizing a component comprising:
a container having a receiving hole for receiving the component into the container;
first and second seal members for sealing an annular surface of the component to thereby form a reaction chamber between the container and the annular surface of the component.

14. The apparatus of claim 13, further comprising a supply passage in the container for introducing a reaction medium into the reaction chamber.

15. The apparatus of claim 14, further comprising a drain passage for draining the reaction medium from the reaction chamber.

16. The apparatus of claim 13, further comprising a first electrode for energizing the component.

17. The apparatus of claim 6, further comprising a second electrode for energizing the container adjacent to the reaction chamber.

18. The apparatus of claim 15, wherein the supply drain passages have openings into the reaction chamber about midway between the first and second seals.

19. The apparatus of claim 15, wherein the container includes a passage plate having an opening for the component to extend through, wherein the passage plate includes a supply groove and a drain groove opening into the reaction chamber.

20. The apparatus of claim 19, wherein the passage plate is positioned about midway between the first and second seals.

21. The apparatus of claim 19, wherein the passage plate is energized by the second electrode

22. The apparatus of claim 21, wherein a portion of the passage plate adjacent to the reaction chamber remains de-energized.

23. The apparatus of claim 19, wherein the supply groove and the drain groove are formed on opposite sides of the passage plate.

24. The apparatus of claim 22, wherein the supply groove and the drain groove extend in a direction generally perpendicular to the surface being anodized.

25. The apparatus of claim 19, wherein the supply groove and the drain groove comprise plural supply grooves and plural drain grooves, the supply grooves and the drain grooves being arranged alternately to each other around the opening in the passage plate.

26. The apparatus of claim 25, wherein each supply groove extends toward the component at a different angle from each drain groove.

27. The apparatus of claim 19, further comprising an electrode rod abutting the passage plate outside the reaction chamber for energizing the passage plate.

28. The apparatus of claim 13, wherein the first and second seal members are placed on flange portions formed in the container, and further comprising:
a push mechanism for compressing the first and second seal members so as to seal the outer surface of the component, the push mechanism including a movable sleeve disposed between the component and the container, and a push rod disposed in the container for pushing the sleeve.

29. The apparatus of claim 27, wherein the first and second sealing members are placed on flange portions formed in the container, and further comprising:
a push mechanism for compressing the first and second seal members so as to seal the outer surface of the component, the push mechanism including a movable sleeve disposed between the component and the container, and a push rod disposed in the container for pushing the sleeve.

30. The apparatus of claim 29, wherein the container includes first and second members separated at the annular surface being anodized, the first and second members being provided with the flange portions for holding thereon the first and second seal members wherein the passage plate is located between the first and second members and the supply passage and the drain passage are each formed in the first member and the second member, respectively, and
wherein the reaction chamber is formed between the first member, the second member, and the annular surface.
